(19) United States
(12) Patent Application Publication
(10) Pub. No.: US 2024/0407092 A1
(43) Pub. Date: Dec. 5, 2024

(54) COVERS FOR INTEGRATED CIRCUIT PACKAGE SOCKETS

(71) Applicant: Intel Corporation, Santa Clara, CA (US)

(72) Inventors: Ariatne Ramirez Macias, Zapopan (MX); Allison Van Horn, Beaverton, OR (US); Kristin L. Weldon, Hillsboro, OR (US); Israel Cruz Ruiz, Zapopan (MX); Fernando Gonzalez Lenero, Zapopan (MX); Min Pei, Camas, WA (US); Francisco Javier Colorado Alonso, San Pedro Tlaquepaque (MX); Randall Scott Sanford, Scappoose, OR (US); Emery Evon Frey, Portland, OR (US); Eric W. Buddrius, Hillsboro, OR (US)

(73) Assignee: Intel Corporation, Santa Clara, CA (US)

(21) Appl. No.: 18/806,367

(22) Filed: Aug. 15, 2024

(51) Int. Cl. H05K 1/11

(52) U.S. Cl. CPC H05K 1/11; H05K 2201/10325

(57) ABSTRACT

Covers for integrated circuit package sockets are disclosed herein. An example cover for a socket for an integrated circuit package includes a base including a cutout, the cutout to engage a pin associated with the socket, engagement of the cutout and the pin to maintain a position of the cover relative to the socket; and a handle to facilitate positioning of the cover to move the cutout into engagement with the pin.

### BACKGROUND

Some integrated circuit packages (e.g., CPUs, GPUs, microprocessors, etc.) are mechanically and electrically connected to a circuit board via a socket coupled to the circuit board. Sockets include an array of contacts (e.g., pins) that interface with corresponding contacts (e.g., pads) on the integrated circuit package when the package is inserted into the socket. Socket types include pin grid array (PGA), land grid array (LGA), ball grid array (BGA), stud grid array (SGA), staggered pin array (SPGA), and reduced pin grid array (rPGA), among others. Sometimes a socket cover is used to cover and protect the array of contacts (e.g., pins) of a socket when no integrated circuit package is installed therein (e.g., during shipping of new sockets).

### BRIEF DESCRIPTION OF THE DRAWINGS

FIG. 1A is an isometric top view of an example rotational socket cover constructed in accordance with teachings of this disclosure.

FIG. 1B is an isometric bottom view of the example rotational socket cover of FIG. 1A.

FIG. 1C is a top view of the example rotational socket cover of FIG. 1A.

FIG. 1D is a side view of the example rotational socket cover of FIG. 1A.

FIG. 1E is a front view of the example rotational socket cover of FIG. 1A.

FIG. 2A is an isometric view of the example rotational socket cover of FIGS. 1A-1E connected to an example socket in accordance with teachings of this disclosure.

FIG. 2B is an isometric view of the example socket of FIG. 2A in accordance with the teachings of this disclosure.

FIG. 3A is a top view of the example rotational socket cover of FIG. 2 in an unlocked position relative to the example socket.

FIG. 3B is a top view of the example rotational socket cover of FIG. 2 in a locked position relative to the example socket.

FIG. 4A is an isometric top view of another example rotational socket cover constructed in accordance with teachings of this disclosure.

FIG. 4B is a top view of the example rotational socket cover of FIG. 4A.

FIG. 5 is a top view of another example rotational socket cover constructed in accordance with teachings of this disclosure.

FIG. 6 is a flowchart of an example process to manufacture the example rotational socket covers of FIGS. 1-5 in accordance with teachings of this disclosure.

FIG. 7 is a flowchart of an example process for installation and removal of the example rotational socket covers of FIGS. 1-5 in accordance with teachings of this disclosure.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

The contact field (e.g., array of pins) of a socket for an integrated circuit package is prone to damage when an integrated circuit package is not connected to (e.g., inserted in) the socket. Damage to the contact field of a socket can render the socket unusable, requiring replacement of the socket for an integrated circuit to be connected to the circuit board. Accordingly, socket covers are often used to provide protection of the contact field of the socket at times when an integrated circuit package is not connected to the socket.

Some known socket covers (e.g., covers) are difficult to install and/or remove from the socket depending on the mechanisms used to attach the cover to the socket assembly. Such difficulties can lead to errors in installation or removal of the cover, which can lead to damage to the contact field. Some known covers fail to provide adequate protection to the contact field even when installed correctly due to the forces experienced by the cover's latching mechanisms during transit. For example, sudden drops may cause known sockets to fall off the socket. In such cases, the contact field can become exposed, opening the contact field to potential damage. Some known covers are prone to deformation when subjected to forces. Such deformation can lead to damage to the contact field. Methods and apparatus disclosed herein provide for improved ease of installation and removal of a rotational socket cover for computer hardware sockets. Rotational socket covers disclosed herein provide increased reliability of protection of the contact field.

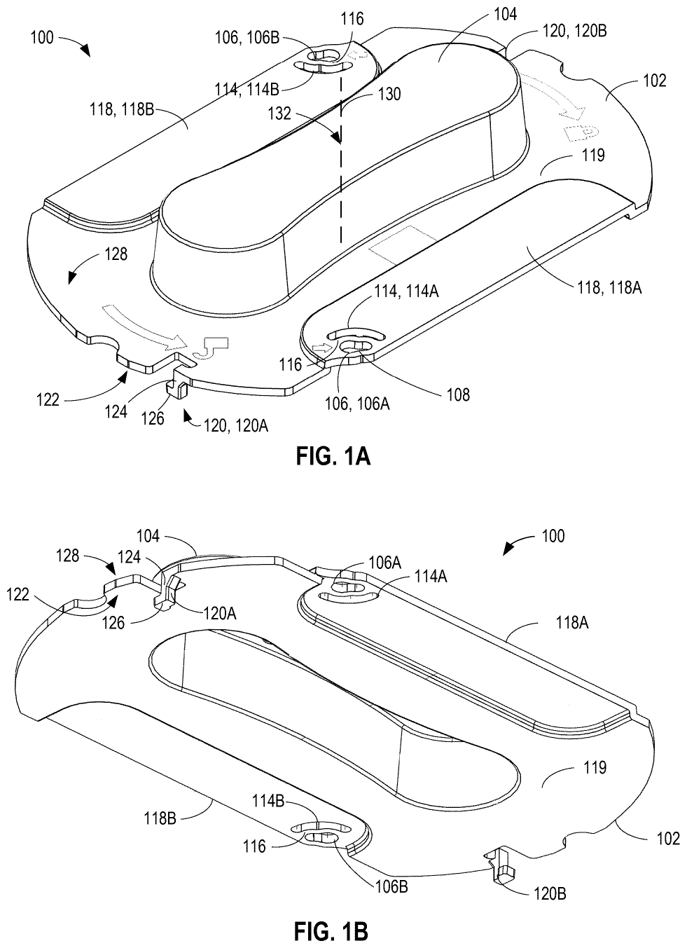

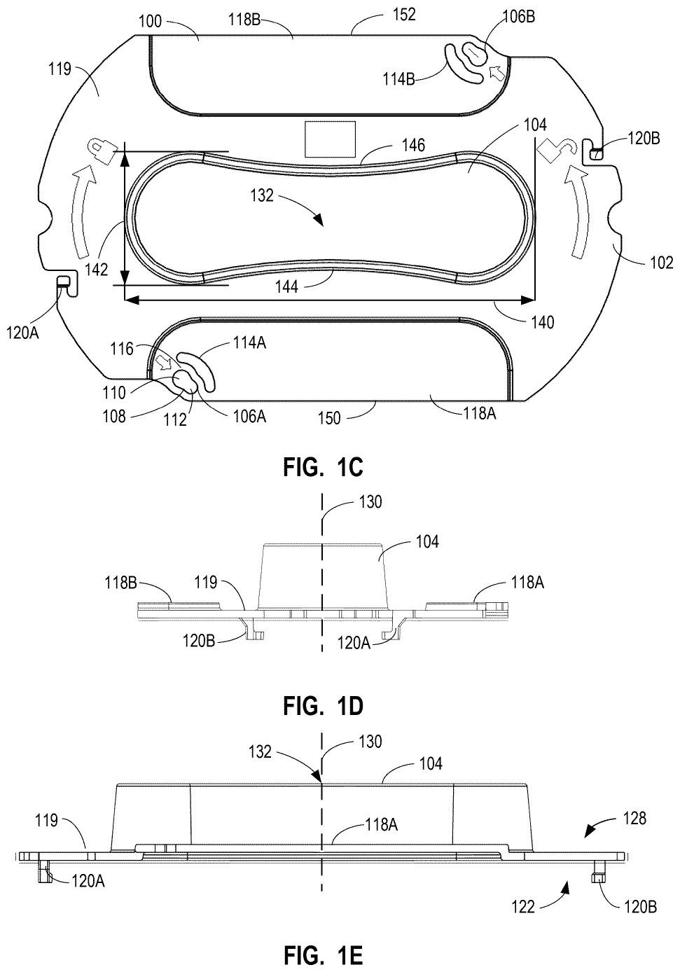

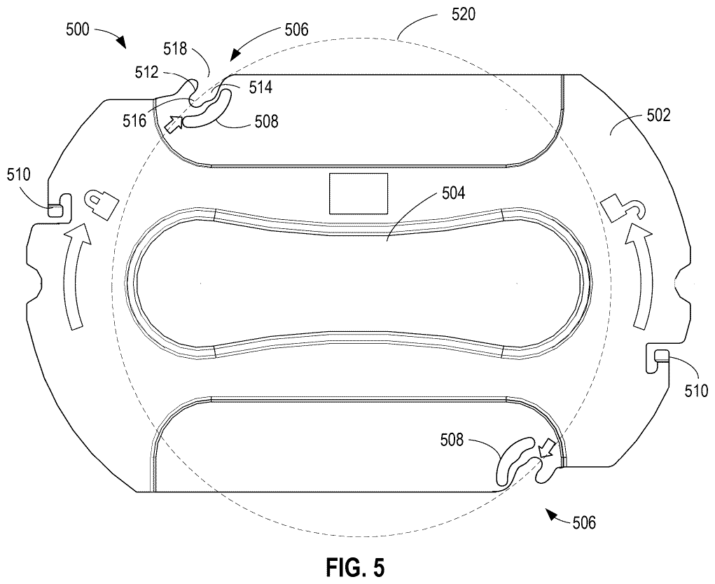

FIGS. 1A-1E illustrate an example cover 100 to connect to a socket. The example cover 100 includes a base 102 (e.g., body, base plate) and a handle 104 (e.g., grip, handgrip). The base 102 includes cutouts 106 (e.g., holes, slots, openings, apertures, etc.). In this example, there are two cutouts 106 identified by reference numbers 106A and 106B. In other examples, a different number of cutouts 106 can be employed. The cutouts 106 engage pins (e.g., posts, columns, pillars, etc.) of the socket. The engagement of the cutouts 106 serves to maintain a position of the cover 100 relative to the socket. In the illustrated example of FIGS. 1A-1E, the cutouts 106 are spaced away from a perimeter of the base 102. In other examples, the cutouts 106 extend to the perimeter of the base 102 (as shown in the illustrated example of FIG. 5). In some examples, different ones of the cutouts 106 can have different shapes and/or different sizes relative to other ones of the cutouts 106 of the socket cover 100.

The cover 100 is movable between an unlocked position and a locked position. In the unlocked position, the cutouts 106 do not engage the pins, permitting movement of the cover 100 relative to the socket. The cover 100 is moved from the unlocked position to the locked position by rotation of the cover 100 relative to the socket. In the locked position, the cutouts 106 engage (e.g., latch onto, grab, grip, retain, receive, etc.) the pins, restricting (e.g., inhibiting, restraining, hindering, preventing, etc.) the movement of the cover 100 relative to the socket. The cover 100 may also be moved from the locked position to the unlocked position by rotation of the cover 100 relative to the socket, disengaging the cutouts 106 from the pins, allowing movement of the cover 100 relative to the socket.

In some examples, the cutouts 106 include necks 108 defined by perimeters of the cutouts that are narrower than the cutouts 106 on either side of the necks 108. In some such examples, the width of the necks 108 is equal to or slightly smaller than the widths of the pins of the socket to be inserted therein. As a result, rotation of the cover 100 cause the pins to press-fit through the necks 108 to move from first sides of the necks 108 to second sides of the necks 108. In some examples, the cutouts 106 include first regions 110 (labelled in FIG. 1C) on the first sides of the necks to enable alignment of the cover 100 to the socket in the unlocked position and second regions 112 (also labelled in FIG. 1C) on the second sides of the necks 108 to engage the pins in the locked position. For example, the pins may be contained within the first regions 110 in the unlocked position, such that the first regions 110 guide the pins into the second regions 112 when the cover 100 is rotated.

In some examples, the cover 100 includes means (e.g., first means) for engaging pins of a socket. For example, the means for engaging may be implemented by the cutouts 106. In other examples, the means for engaging pins of a socket may include a hook and loop fastener, a clasp, a clamp, and/or other types of fasteners/joints.

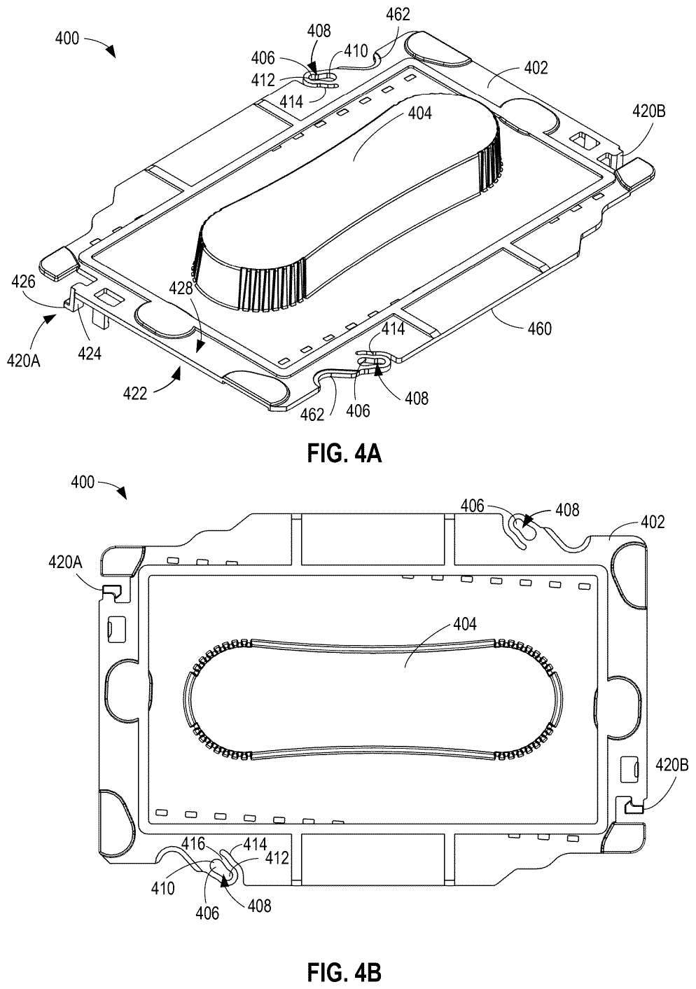

As shown in the illustrated example of FIGS. 1A-1E, the base 102 includes relief cutouts 114 adjacent to the cutouts 106, portions 116 of the base 102 between the cutouts 106 and respective relief cutouts 114. The relief cutouts 114 reduce an amount of rotational force required to move the cover 100 from the unlocked position to the locked position (or from the locked position to the unlocked position). The portions 116 of the base 102 have a stiffness based on the material of the base 102 and the structure of the base 102. Inclusion of the relief cutouts 114 reduces the stiffness of the portions 116, enabling the necks 108 to flex and snap around the pins more easily as the cover 100 is rotated into the locked position (or rotated to be removed from the locked position). In the illustrated example of FIGS. 1A-1E, the relief cutouts 114 are spaced away from a perimeter of the base 102. In other examples, the relief cutouts 114 extend to (e.g., are open along) the perimeter of the base 102 (as shown in the illustrated example of FIGS. 4A-4B). In some examples, the base 102 does not include relief cutouts 114.

As shown in the illustrated example, the base 102 includes one or more raised regions 118 that jut outward from (e.g., above) a baseline region 119. In this example, the cutouts 106 and the relief cutouts 114 are in the raised regions 118. In the illustrated example, a first cutout 106A and a first relief cutout 114A are in a first raised region 118A and a second cutout 106B and a second relief cutout 114b are in a second raised region 118A. In some examples, one or more of the cutouts 106 and/or one or more of the relief cutouts 114 are in the baseline region 119. In some examples, the base 102 does not include raised regions 118.

In some examples, the base 102 includes one or more hooks 120. As best illustrated in FIG. 1B, the hooks 120 are on a side 122 of the base 102 (e.g., a first side of the base) facing toward the socket. The hooks 120 extend away from the base 102 and interface with the socket to limit (e.g., restrict, inhibit, restrain, hinder, etc.) movement of the cover 100 relative to the socket in a direction away from the socket (e.g., a direction normal to a face of the first side 122 of the base 102). More particularly, in this example, the hooks 120 extend away from the baseline region 119 of the base 102. In other examples, one or more hooks 120 may additionally or alternatively extend away from one or more of the raised regions 118. In some examples, the hooks 120 include legs 124 extending away from the base 102 and feet 126 (e.g., tips, ends, etc.) that extend transverse to the legs 124. In some examples, the feet 126 extend substantially parallel to the base 102. As used herein, substantially parallel means exactly parallel or within 5 degrees of exactly parallel. In some examples, the feet 126 limit movement of the cover 100 in the direction away from the socket. In the illustrated example of FIGS. 1A-1E, the base 102 includes a first hook 120A on a first end of the base 102 and a second hook 120B on a second end of the base 102. In some examples, the base 102 includes a first plurality of hooks 120 on the first end of the base 102 and a second plurality of hooks 120 on the second end of the base 102. In some examples, one or more hooks 120 can be positioned at any other suitable location on the base 102. In some examples, the hooks 120 are omitted.

In some examples, the cover 100 includes means for restricting movement of the cover 100 away from the socket. For example, the means for restricting may be implemented by the hooks 120. In other examples, the means for reducing may include clips, overhangs, cutouts, and/or other types of fasteners/joints.

As shown in the illustrated example of FIGS. 1A-1E, the handle 104 protrudes from the base 102 on a second side 128 of the base 102 opposite the first side 122 of the base 102. More particularly, in this example, the handle 104 protrudes from the baseline region 119 of the base 102. In other examples, the handle 104 may additionally or alternatively protrude from one or more of the raised regions 118. In some examples, the handle 104 is centered on the base 102 around a center point 132. The handle 104 facilitates positioning of the cover 100 relative to the socket to move the cutouts 106 into engagement with the pins. The cover 100 is rotated about an axis 130 located at the center point 132. The handle 104 also facilitates positioning of the cover 100 relative to the socket to move the cutouts 106 out of engagement with the pins (e.g., disengagement of the cutouts 106 with the pins). The handle 104 provides a surface for a user to grip the cover 100 for installation and removal of the cover 100. In some examples, a size of the handle 104 and a position of the handle 104 on the base 102 is independent of a size of the base 102. As shown in FIG. 1C, the handle 104 has a length 140 and a width 142. In this example, the handle 104 is elongate with the length substantially longer (e.g., at least twice as long, at least three times as long, etc.) than the width 142. In other examples, the length 140 and the width 142 can be closer (e.g., identical) in size. In some examples, the width 142 of the handle 104 is less than half of an overall width of the base 102, while the length 140 of the handle 104 is more than half of an overall length of the base 102. The handle 104 has a first side 144 and a second side 146. In some examples, the first side 144 of the handle is spaced apart from (e.g., inset relative to) a first edge 150 of the base 102 and the second side 146 of the handle is spaced apart from (e.g., inset relative to) a second edge 152 of the base 102. In some examples, the cover 100 includes means for enabling manual rotation of the base 102. For example, the means for enabling may be implemented by the handle 104. In other examples, the means for enabling may be implemented by a knob, one or more slots, one or more holes, a rod, and/or other surface a user may grab to rotate the cover 100.

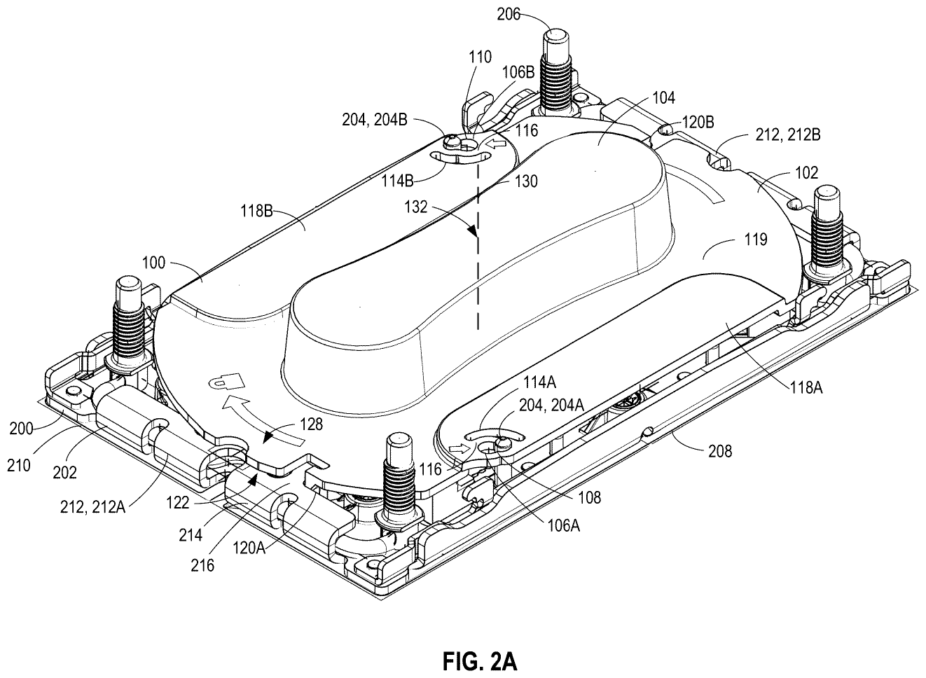

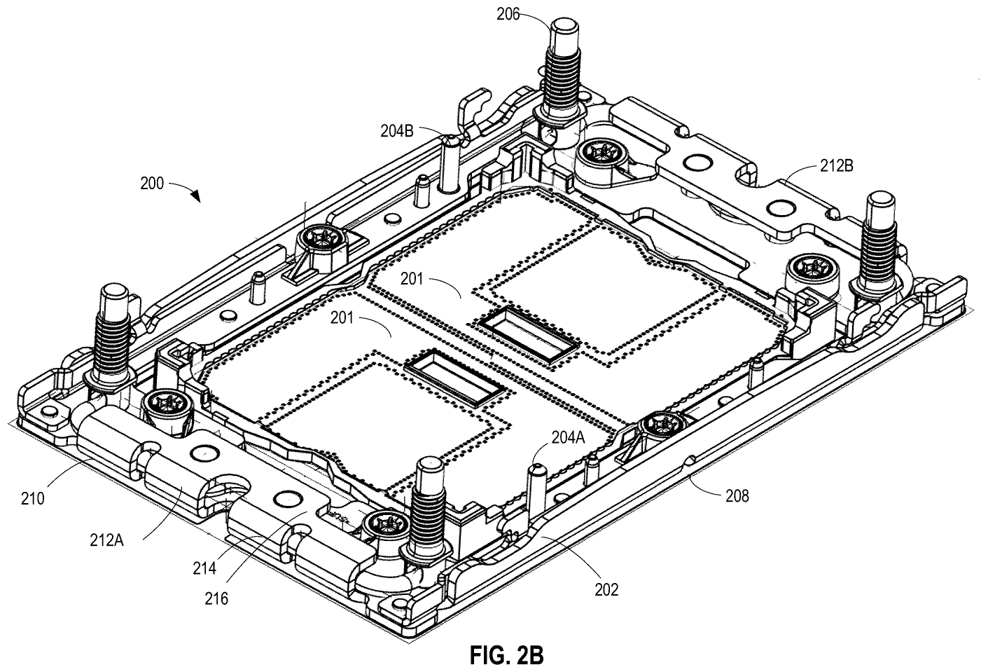

FIG. 2A is an isometric view of the example cover 100 of FIG. 1A-1E connected to an example socket 200. FIG. 2B is an isometric view of the example socket 200 of FIG. 2A with the cover 100 removed. In the illustrated example of FIGS. 2A and 2B, the socket 200 is a CPU socket. In other examples, the socket 200 enables placement and removal of integrated circuit packages other than a CPU, such as a GPU. The socket 200 may be a PGA socket, an LGA socket, or any other type of socket (e.g., BGA, SGA, SPGA, rPGA, etc.). The socket 200 includes a contact field 201, a bolsterplate 202, pins 204, and load posts 206. In some examples, the bolster plate 202 is separate from the socket 200. In the illustrated example, the pins 204 are located on the bolsterplate 202. In other examples, the pins 204 are located elsewhere on the socket 200 or adjacent to the socket 200 on a circuit board (not shown) to which the socket 200 is attached. The socket 200 has a length 208 and a width 210.

In the locked position, the pins 204 are retained in the second regions 112 of the cutouts 106, restricting the movement of the cover 100 relative to the socket 200. In some examples, the first regions 110 have a first width, the second regions 112 have a second width smaller than the first width, and the necks 108 have a third width equal to or smaller than the second width. In some examples, the third width is equal to or smaller than a fourth width of the pins 204. However, in some examples, the first width (of the first regions 110) is greater than the fourth width of the pins 204. As a result, in those examples, first perimeters of the first regions 110 and the pins form clearance fits when the pins 204 are in the first regions 110. As used herein, a clearance fit means there is a gap between the two surfaces that form the fit. This allows the cover 100 to move relative to the pins 204 when the pins 204 are in the first regions 110. Second perimeters of the second regions 112 and the pins 204 form interference fits (e.g., pressed fits, friction fits) when the pins 204 are in the second regions 112. As used herein, an interference fit means the two surfaces which form the interference fit are held together by friction once they are fit together. When the pins 204 are in the second regions 112, the interference fits between the perimeters of the second regions 112 and the pins 204 restrict movement of the cover 100 away from the socket 200 in a first direction normal to the socket (e.g., a vertical direction), and the necks 108 flex around the pins 204 to restrict both translational and rotational movement of the cover 100 relative to the socket 200 in a direction orthogonal to the first direction (e.g., a horizontal direction). The fourth width of the pins 204 is larger than the third width of the necks 108, causing the pins 204 to remain in the second regions 112 of the cutouts 106 until a sufficient amount of rotational force is applied to force the pins 204 across the necks 108.

In some examples, the pins 204 may each include a top segment, a bottom segment, and a groove between the top and bottom segment to interface with the cutouts 106 to restrict movement in the first direction. In some examples, a width of the pins 204 at the grooves is smaller than a width of the pins 204 at the top segments and bottom segments. In such examples, portions of perimeters of the cutouts 106 may be moved into the respective grooves of the pins 204 such that the portions of the perimeters of the cutouts are restricted from moving in the first direction by the top segments and bottom segments of the pins 204. In some examples, the pins 204 include necks and heads. In those examples, a width of the heads is larger than a width of the necks and a width of the second regions 112 of the cutouts 106 such that the heads restrict the cover 100 from moving away from the socket 200 in the first direction when the pins 204 are in the second regions 112. In such examples, the width of the heads is smaller than a width of the first regions 110 of the cutouts 106, such that the heads do not restrict movement of the cover 100 towards or away from the socket 200 when the pins 204 are in the first regions 110.

In some examples, the bolster plate 202 includes ridges 212 (e.g., flanges, edges, rims, lips, etc.) to interface with the hooks 120. In the illustrated example of FIG. 2, the ridges 212 include first portions 214 extending away from the socket 200 in the first direction and second portions 216 extending substantially parallel to a plane of the socket 200. The second portions 216 are spaced apart from a surface of the socket 200. The hooks 120 extend away from the base 102 and extend around the ridges 212 of the socket 200. More specifically, the legs 124 and the feet 126 of the hooks 120 extend around (e.g., underneath) the second portions 216, and the feet 126 interface with undersides of the second portions 216 to restrict movement of the cover 100. In the illustrated example of FIG. 2, the base 102 includes a first hook 120A to extend around a first ridge 212A and a second hook 120B to extend around a second ridge 212B. In some examples, the base 102 includes a first plurality of hooks 120 extending around the first ridge 212A and a second plurality of hooks extending around the second ridge 212B.

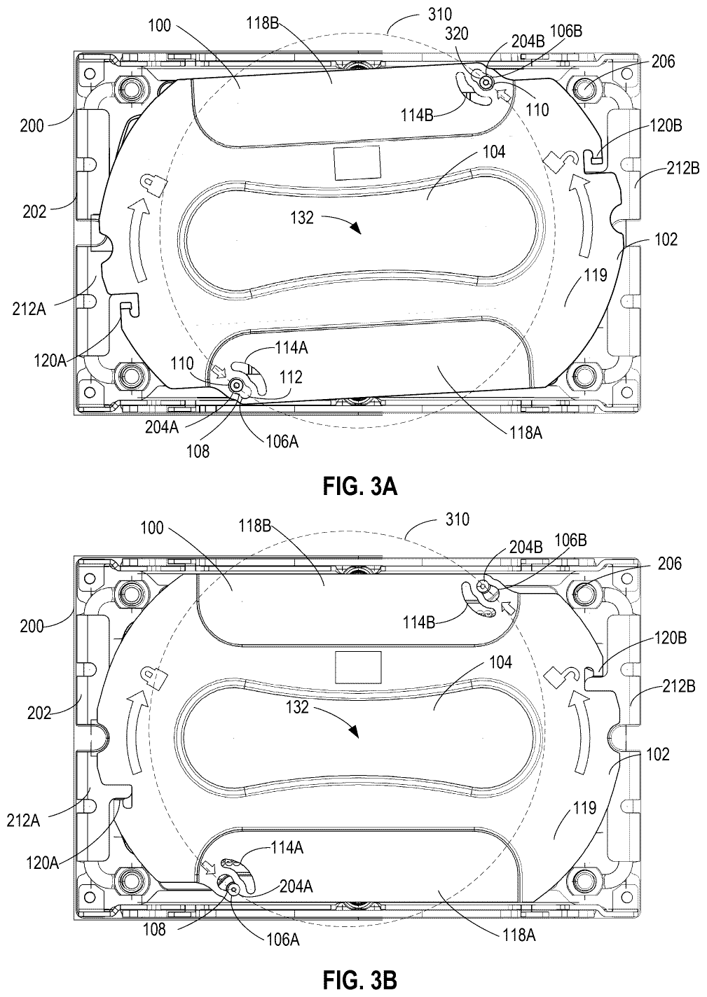

FIG. 3A is a top view of the example rotational socket cover 100 in an unlocked position relative to the example socket 200. In the unlocked position, the pins 204 are in the first regions 110. The first regions 110 and the pins 204 form a clearance fit such that the cover 100 is not restricted from moving relative to the socket 200. The necks 108 of the cutouts 106 have a third width less than the first width of the first regions 110 and less than or equal to the second width of the second regions 112. The third width of the necks 108 are smaller than the fourth with of the pins 204 to prevent the pins 204 being moved across the necks 108 without sufficient amount of rotational force being applied to the cover 100 relative to the socket 200. In the unlocked position, the hooks 120 do not extend around (e.g., underneath) the flanges 212 of the socket 200. Thus, the hooks 120 do not restrict the cover 100 from moving in the first direction away from the socket 200.

The cover 100 is moved from the unlocked position to the locked position by rotation of the cover 100 relative to the socket 200. The socket is rotated about the axis 130 (shown in FIGS. 1A, 1D-1E) located at the center point 132 such that the cutouts 106 follow a circular path 310 when the cover 100 is rotated. The axis 130 extends through the handle 104. The example cutouts 106 are elongate and are oriented such that a lengthwise centerline of the cutouts 106 is tangential to the circular path 310. Rotation of the cover 100 causes the pins 204 to be forced through the necks 108 and into the second regions 112. In this example, both the first and second cutouts 106A, 106B are positioned along the same circular path 310 and circumferentially spaced apart by 180 degrees along the circular path 310. In other words, the first and second cutouts 106A, 106B define a line that passes through the center point 132 with the cutouts 106A, 106B being on opposites sides of the center point 132 and spaced the same distance from the center point 132. In other examples, different cutouts 106 can be positioned at different circumferential spacings from one and/or can be positioned on different circular paths (of different radius from the center point).

In the illustrated example of FIGS. 3A-3B, the cover 100 is rotated clockwise in a plane defined by the base 102 in order to move the cover 100 from the unlocked position to the locked position. In other examples, the cover 100 is rotated counterclockwise to move the cover 100 from the unlocked position to the locked position. In those examples, the orientation of the cutouts 106 and the relief cutouts 114 may differ from what is shown in FIGS. 1A-3B in order to enable locking of the cover 100 by counterclockwise rotation. For example, the cutouts 106 may be rotated 180 degrees in the plane defined by the base 102 around respective center points 320.

FIG. 3B is a top view of the rotational socket cover 100 in a locked position relative to the socket 200. In the locked position, the pins 204 are in the second regions 112. The second regions 110 and the pins 204 form an interference fit such that the cover 100 is restricted from moving relative to the socket 200. The necks 108 snap around the pins 204 to retain the pins 204 in the second regions and prevents the pins 204 from being moved across the necks 108 without sufficient amount of rotational force being applied to the cover 100 relative to the socket 200. In the locked position, the hooks 120 extend around (e.g., underneath) the flanges 212 of the socket 200. Thus, the hooks 120 restrict the cover 100 from moving in the first direction away from the socket 200.

FIGS. 4A-4B illustrate another example cover 400 to connect to a socket. The example cover 400 includes a base 402 and a handle 404. The base 402 includes one or more cutouts 406. In some examples, the cutouts 406 may be the same or similar to the cutouts 106 shown and described above in connection with FIGS. 1A-3B. As such, the description of the cutouts 106 discussed above may be suitably applied to the cutouts 406 in FIGS. 4A-4B. Thus, in some examples, the cutouts 406 engage corresponding pins of the socket. The cutouts 406 include necks 408 defined by perimeters of the cutouts. Rotation of the cover 400 causes the pins to move from first regions 410 on a first side of the necks 408 to second regions 412 on a second side of the necks 408.

The base 402 includes one or more relief cutouts 414 adjacent to the cutouts 406. The relief cutouts 414 are separated from the cutouts 406 by narrow portions 416 of the base 402. Inclusion of the relief cutouts 414 reduces the stiffness of the portions 416, enabling the necks 408 to flex and snap around the pins more easily as the cover 400 is rotated into the locked position. In this example, the relief cutouts 414 extend to the perimeter of the base 402.

The base 402 includes one or more hooks 420 (individually identified by reference numbers 420A and 420B). In some examples, the hooks 420 may be the same or similar to the hooks 120 shown and described above in connection with FIGS. 1A-1E and 2. As such, the description of the hooks 120 discussed above may be suitably applied to the hooks 420 in FIGS. 4A-4B. The first and second hooks 420A, 420B are on a side 422 of the base 402 facing toward the socket. The first and second hooks 420A, 420B extend away from the base 402 and interface with the socket to limit movement of the cover 400 relative to the socket in a direction away from the socket. As shown in the illustrated example, the hooks 420 include legs 424 extending away from the base 402 and feet 426 (e.g., tips, ends, etc.) extending transverse to the legs 424 (e.g., substantially parallel to the base 402). In those examples, the feet 426 limit movement of the cover 400 in the direction away from the socket. In some examples, the hooks 420 are omitted.

In the illustrated example of FIGS. 4A-4B, a perimeter 460 of the base 402 defines notches 462. In some examples, the notches 462 interface with (e.g., contour, align with, etc.) respective load posts of the socket when the cover 400 is in the unlocked position. This enables easier alignment of the cover 400 and the socket in the unlocked position, reducing the difficulty of and the time it takes to place the cover 400 on the socket. In some examples, the notches 462 are omitted. In some examples, notches similar to the notches 462 shown in FIGS. 4A-4B are included in the example cover 100 of FIGS. 1A-3B.

The handle 404 protrudes from the base 402 on a second side 428 of the base 402 opposite the first side 422 of the base 402. The handle 404 provides a surface for a user to grip the cover 400 for installation and removal of the cover 400.

FIG. 5 is a top view of another example rotational socket cover 500 to connect to a socket. The example cover 500 includes a base 502 and a handle 504. The base 502 includes cutouts 506 to engage pins of the socket, relief cutouts 508 adjacent to the cutouts, and hooks 510. In some examples, the cutouts 506, the relief cutouts 508, and the hooks 510 may be the same or similar to the cutouts 106, 406, the relief cutouts 114, 414, and the hooks 120, 420 shown and described above in connection with FIGS. 1A-4B except as otherwise noted below. As such, the description of the cutouts 106, 406, the relief cutouts 114, 414, and the hooks 120, 420 discussed above may be suitably applied to the cutouts 506, the relief cutouts 508, and the hooks 510 in FIG. 5.

As shown in the illustrated example of FIG. 5, the cutouts 506 include necks 512 defined by perimeters of the cutouts, rotation of the cover 500 to cause the pins to move from first regions 514 on a first side of the necks 512 to second regions 516 on a second side of the necks 512. The cutouts 506 extend to a gap 518 at a perimeter of the base 502. More specifically, the first regions 514 of the cutouts 506 extend to the gap 518 at the perimeter of the base 502. The extension of the cutouts 506 to the gap 518 enables positioning of the cover 500 in the unlocked position without needing to vertically align the cutouts 506 with the pins of the socket. The pins can enter the first regions 514 from a direction normal to a plane defined by the base 502 (e.g., enter vertically), or a direction parallel to the plane defined by the base 502 (e.g., enter horizontally) through the gap 518. In the illustrated example of FIG. 5, the cutouts 506 are elongate and are oriented such that a lengthwise centerline of the cutouts 506 is tangential to the circular path 520. Rotation of the cover 500 causes the pins to be forced through the necks 512 and into the second regions 516.

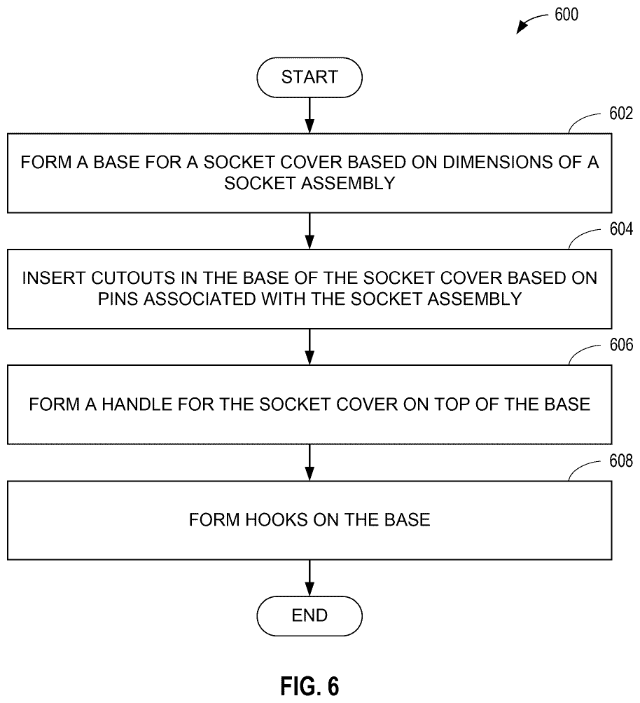

FIG. 6 is a flowchart of an example process 600 to manufacture the example rotational socket covers 100, 400, 500 of FIGS. 1-5 in accordance with teachings of this disclosure. The example process 600 of FIG. 6 begins at block 602, at which a base 102, 402, 502 for the socket cover 100, 400, 500 is formed based on the dimensions of a socket assembly. In some examples, a size and shape of the base 102, 402, 502 are determined based on the size, shape, and/or type of socket the socket cover 100, 400, 500 will be used to protect. For example, the base 102, 402, 502 may be formed such that a width of the base 102, 402, 502 is smaller than or equal in size to a width of the socket assembly and a length of the base 102, 402, 502 is smaller than or equal in size to a length of the socket assembly. In some examples, the base 102, 402, 502 is machined, injection molded, casted, and/or additively formed.

At block 604, cutouts 106, 406, 506, 114, 414, 508 are inserted into the base 102, 402, 502. The number, the location, the size, and/or the shape of the cutouts 106, 406, 506, 114, 414, 508 are determined based on the number, the locations, the size, and/or the shape of pins 204 associated with the socket assembly. For example, the cutouts 106, 406, 506, 114, 414, 508 are formed with a size and shape such that a portion of the perimeter of the cutouts 106, 406, 506, 114, 414, 508 and the pins 204 form an interference fit. In some examples, some or all of the cutouts 106, 406, 506, 114, 414, 508 are formed or provided concurrently with (e.g., during the same operation as) the formation of the base 102, 402, 502 at block 602. In some examples, some or all of the cutouts 106, 406, 506, 114, 414, 508 are formed or provided in a separate operation following formation of the base 102, 402, 502 (e.g., the cutouts 106, 406, 506 may be stamped, punched, or cut out of the previously formed base 102, 402, 502).

At block 606, a handle 104, 404, 504 is formed on a first side of the base 102, 402, 502 for the socket cover 100, 400, 500. In some examples, the handle 104, 404, 504 is formed in the center of the top surface of the base 102, 402, 502. In some examples, the handle 104 is machined, injection molded, casted, and/or additively formed. In some examples, the handle 104, 404, 504 and the base 102, 402, 502 are integrally formed. In some such examples, the handle 104, 404, 504 is formed or provided concurrently with (e.g., during the same operation as) the formation of the base 102, 402, 502 at block 602. In other examples, the handle 104 is formed or provided in a separate operation following the formation of the base 102, 402, 502. In some examples, the handle 104, 404, 504 and the base 102, 402, 502 are mechanically joined, adhesively bonded, welded together, etc.

At block 608, hooks 120, 420, 520 are formed on a second side of the base 102, 402, 502 opposite the first side of the base 102, 402, 502. In some examples, at least two hooks 120, 420, 520 are formed on the second side of the base 102, 402, 502. In some examples, the at least two hooks 120, 420, 520 are formed in opposite positions on the base 102, 402, 502. In some examples, a size, shape, and/or number of hooks 120, 420, 520 formed on the base 102, 402, 502 is determined based on flanges 212 of the socket assembly. For example, the length of the hooks 120, 420, 520 may be determined based on the size and/or shape of the flanges 212. In some examples, the hooks 120, 420, 520 and the base 102, 402, 502 are integrally formed. In some such examples, the hooks 120, 420, 520 are formed or provided concurrently with (e.g., during the same operation as) the formation of the base 102, 402, 502 at block 602. In other examples, the hooks 120, 420, 520 are formed or provided in a separate operation following the formation of the base 102, 402, 502. In some examples, the hooks 120, 420, 520 and the base 102, 402, 502 are mechanically joined, adhesively bonded, welded together, etc. In some examples, block 608 is omitted.

In some examples, any combination of blocks 602, 604, 606, and 608 of example process 600 may be performed collectively. For example, each of blocks 602-608 may be performed in a single action if the cover 100, 400, 500 is manufactured by injection molding. Further, in some examples, where different ones of the blocks are implemented as separate operations, the order of the blocks may be rearranged into any suitable order.

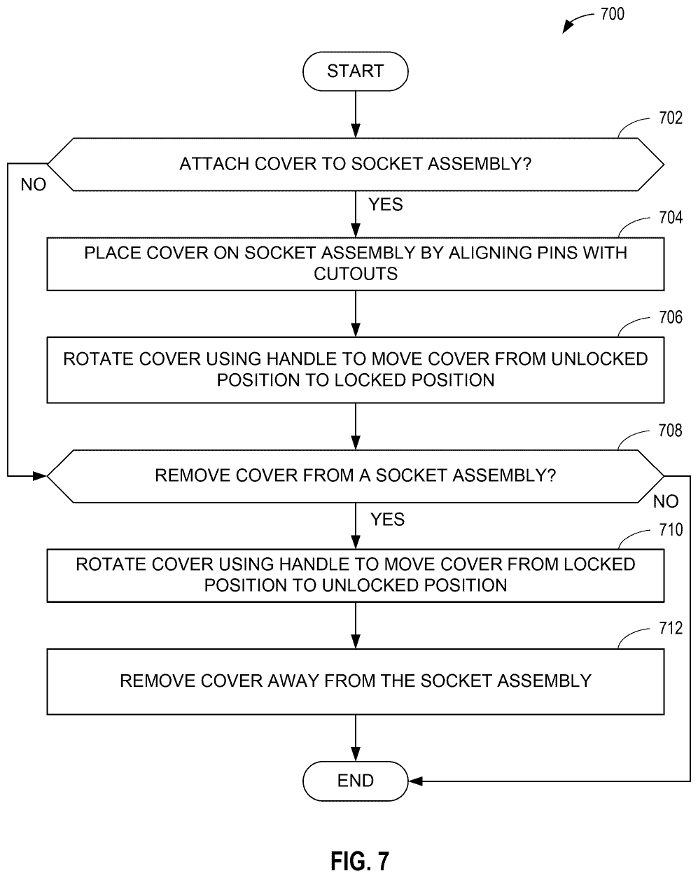

FIG. 7 is a flowchart of an example process 700 for attaching and removing the example rotational socket covers 100, 400, 500 of FIGS. 1-5. The example process 700 of FIG. 7 begins at block 702, at which it is determined whether to attach the cover 100, 400, 500 to a socket assembly. If it is decided to not attach the cover 100, 400, 500 (e.g., block 702 returns a result of NO) the process 700 proceeds to block 708. If it is decided to attach the cover 100, 400, 500 (e.g., block 702 returns a result of YES), the socket cover is placed on the socket assembly at block 704. Cutouts 106, 406, 506 of the cover 100, 400, 500 are aligned with pins 204 and the pins 204 are inserted into first regions 110, 410, 510 (e.g., larger regions) of the cutouts 106, 406, 506.

At block 706, the cover 100, 400, 500 is rotated to move the cover 100, 400, 500 from an unlocked position to a locked position. In the unlocked position, the pins 204 are in the first regions 110, 410, 510. The first regions 110, 410, 510 and the pins 204 form a clearance fit, such that the cover 100, 400, 500 can move relative to the socket assembly without restriction from the pins 204. In the locked position, the pins 204 are in second regions 112, 412, 512. The second regions 112, 412, 512 and the pins 204 form an interference fit, such that the cover 100, 400, 500 is restricted from moving relative to the socket assembly by the interference fit. In some examples, the cover 100, 400, 500 is rotated using a handle 104, 404, 504 of the cover 100, 400, 500. In some examples, the cover 100, 400, 500 is rotated clockwise to move the cover 100, 400, 500 from the unlocked position to the locked position. In other examples, the cover 100, 400, 500 is rotated counterclockwise to move the cover 100, 400, 500 from the unlocked position to the locked position.

At block 708, it is determined whether to remove the cover 100, 400, 500 from the socket assembly. If it is decided to not remove the cover 100, 400, 500 (e.g., block 708 returns a result of NO) the process 700 ends. If it is decided to remove the cover 100, 400, 500 (e.g., block 708 returns a result of YES), the cover 100, 400, 500 is rotated to move the cover 100, 400, 500 from the locked position to the unlocked position at block 710. At block 712, the cover 100, 400, 500 is removed away from the socket assembly.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

From the foregoing, it will be appreciated that example systems, apparatus, articles of manufacture, and methods have been disclosed that improve ease of installation and removal of a socket cover for integrated circuit package sockets. Rotational socket covers disclosed herein provide increased reliability of protection of the contact field of the socket relative to known socket covers. Disclosed systems, apparatus, articles of manufacture, and methods are accordingly directed to one or more improvement(s) in the operation of a machine such as a computer or other electronic and/or mechanical device.

Covers for integrated circuit package sockets are disclosed. Further examples and combinations thereof include the following:

Example 1 includes a cover for a socket for an integrated circuit package, the cover including a base including a cutout, the cutout to engage a pin associated with the socket, engagement of the cutout and the pin to maintain a position of the cover relative to the socket; and a handle to facilitate positioning of the cover to move the cutout into engagement with the pin.

Example 2 includes the cover of example 1, wherein the base includes a relief cutout adjacent to the cutout.

Example 3 includes the cover of any of examples 1 or 2, wherein the relief cutout extends to a perimeter of the base.

Example 4 includes the cover of any of examples 1-3, wherein the relief cutout is spaced apart from a perimeter of the base.

Example 5 includes the cover of any of examples 1-4, wherein the cover is movable between a locked position and an unlocked position by rotation of the cover relative to the socket, the cutout to engage the pin in the locked position, the cutout to disengage from the pin in the unlocked position, disengagement of the cutout and the pin to permit a change in the position of the cover relative to the socket.

Example 6 includes the cover of any of examples 1-5, further including a hook extending away from the base, the hook on a first side of the base, the first side of the base to face towards the socket, the hook to extend around a ridge of the socket in the locked position to restrict movement of the cover relative to the socket in a direction normal to a face of the first side of the base.

Example 7 includes the cover of any of examples 1-6, wherein the rotation is about an axis defined by a direction normal to a face of the base facing away from the socket.

Example 8 includes the cover of any of examples 1-7, wherein the axis is to pass through the handle.

Example 9 includes the cover of any of examples 1-8, wherein a perimeter of the base defines a notch that is to interface with a load post of a bolster plate associated with the socket when the cover is in the unlocked position.

Example 10 includes the cover of any of examples 1-9, wherein the handle protrudes from a center of the base.

Example 11 includes the cover of any of examples 1-10, wherein a portion of a perimeter of the cutout engages a groove of the pin.

Example 12 includes the cover of any of examples 1-11, wherein the base includes a first region and a second region, the first region raised relative to the second region in a direction away from the socket when the cutout is in engagement with the pin, the cutout in the first region.

Example 13 includes the cover of any of examples 1-12, wherein the pin includes a neck and a head, the head larger than the neck, the cutout dimensioned to engage the neck of the pin and not engage the head of the pin.

Example 14 includes the cover of any of examples 1-13, wherein the cutout is a first cutout in a first location of the base and the pin is a first pin, the base further including a second cutout in a second location of the base to engage a second pin associated with the socket, the center of the base between the first location and the second location.

Example 15 includes a socket cover including a body including an opening, the opening to receive a column associated with a socket for an integrated circuit package, reception of the column by the opening to restrict movement of the socket cover relative to the socket; and a handle on a first side of the body, the first side of the body to face away from the socket, the handle to be located over a center of the socket when the column is received by the opening.

Example 16 includes the socket cover of example 15, wherein the opening is elongate and includes: a first region at a first end, the first region having a first width; a second region at a second end, the second region having a second width smaller than the first width; and a neck between the first region and the second region, the neck having a third width, the third width smaller than the first width and the third width smaller than a fourth width of the column.

Example 17 includes the socket cover of any of examples 15 or 16, wherein a first perimeter of the first region and the column form a clearance fit when the column is in the first region, and a second perimeter of the second region and the column form an interference fit when the column is in the second region.

Example 18 includes the socket cover of any of examples 15-17, wherein rotation of the socket cover is to cause the column to be forced through the neck from the first region into the second region, the second region to retain the column in a locked position.

Example 19 includes an apparatus including a base plate to cover a pin field of a socket for an integrated circuit package, the base plate including a slot, the slot to latch onto a post associated with the socket when the base plate is rotated in a first direction relative to the socket, the slot to release the post when the base plate is rotated in a second direction opposite the first direction; and a grip connected to the base to facilitate selective rotation of the base plate in the first and second directions.

Example 20 includes the apparatus of example 19, wherein a width of the grip is less than half a width of the base plate.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A cover for a socket for an integrated circuit package, the cover comprising:
a base including a cutout, the cutout to engage a pin associated with the socket, engagement of the cutout and the pin to maintain a position of the cover relative to the socket; and
a handle to facilitate positioning of the cover to move the cutout into engagement with the pin.

2. The cover of claim 1, wherein the base includes a relief cutout adjacent to the cutout.

3. The cover of claim 2, wherein the relief cutout extends to a perimeter of the base.

4. The cover of claim 2, wherein the relief cutout is spaced apart from a perimeter of the base.

5. The cover of claim 1, wherein the cover is movable between a locked position and an unlocked position by rotation of the cover relative to the socket, the cutout to engage the pin in the locked position, the cutout to disengage from the pin in the unlocked position, disengagement of the cutout and the pin to permit a change in the position of the cover relative to the socket.

6. The cover of claim 5, further including a hook extending away from the base, the hook on a first side of the base, the first side of the base to face towards the socket, the hook to extend around a ridge of the socket in the locked position to restrict movement of the cover relative to the socket in a direction normal to a face of the first side of the base.

7. The cover of claim 5, wherein the rotation is about an axis defined by a direction normal to a face of the base facing away from the socket.

8. The cover of claim 7, wherein the axis is to pass through the handle.

9. The cover of claim 5, wherein a perimeter of the base defines a notch that is to interface with a load post of a bolster plate associated with the socket when the cover is in the unlocked position.

10. The cover of claim 1, wherein the handle protrudes from a center of the base.

11. The cover of claim 1, wherein a portion of a perimeter of the cutout engages a groove of the pin.

12. The cover of claim 1, wherein the base includes a first region and a second region, the first region raised relative to the second region in a direction away from the socket when the cutout is in engagement with the pin, the cutout in the first region.

13. The cover of claim 1, wherein the pin includes a neck and a head, the head larger than the neck, the cutout dimensioned to engage the neck of the pin and not engage the head of the pin.

14. The cover of claim 1, wherein the cutout is a first cutout in a first location of the base and the pin is a first pin, the base further including a second cutout in a second location of the base to engage a second pin associated with the socket, the center of the base between the first location and the second location.

15. A socket cover comprising:
a body including an opening, the opening to receive a column associated with a socket for an integrated circuit package, reception of the column by the opening to restrict movement of the socket cover relative to the socket; and
a handle on a first side of the body, the first side of the body to face away from the socket, the handle to be located over a center of the socket when the column is received by the opening.

16. The socket cover of claim 15, wherein the opening is elongate and includes:
a first region at a first end, the first region having a first width;
a second region at a second end, the second region having a second width smaller than the first width; and
a neck between the first region and the second region, the neck having a third width, the third width smaller than the first width, the third width smaller than a fourth width of the column.

17. The socket cover of claim 16, wherein a first perimeter of the first region and the column form a clearance fit when the column is in the first region, and a second perimeter of the second region and the column form an interference fit when the column is in the second region.

18. The socket cover of claim 17, wherein rotation of the socket cover is to cause the column to be forced through the neck from the first region into the second region, the second region to retain the column in a locked position.

19. An apparatus comprising:
a base plate to cover a pin field of a socket for an integrated circuit package, the base plate including a slot, the slot to latch onto a post associated with the socket when the base plate is rotated in a first direction relative to the socket, the slot to release the post when the base plate is rotated in a second direction opposite the first direction; and
a grip connected to the base plate to facilitate selective rotation of the base plate in the first and second directions.

20. The apparatus of claim 19, wherein a width of the grip is less than half a width of the base plate.
